(19) United States
(12) Patent Application Publication
(10) Pub. No.: US 2018/0012890 A1
(43) Pub. Date: Jan. 11, 2018

(54) SEMICONDUCTOR DEVICE AND MANUFACTURING METHOD THEREOF

(71) Applicant: CSMC TECHNOLOGIES FAB2 CO., LTD., Wuxi New District, Jiangsu (CN)

(72) Inventors: Wei LI, Wuxi New District (CN); Long HAO, Wuxi New District (CN); Yan JIN, Wuxi New District (CN); Dejin WANG, Wuxi New District (CN)

(21) Appl. No.: 15/547,239

(22) PCT Filed: Sep. 23, 2015
(86) PCT No.: PCT/CN2015/090476

§ 371 Date: Jul. 28, 2017

(30) Foreign Application Priority Data
Jan. 29, 2015 (CN) 201510048182.4

(51) Int. Cl. H01L 27/092; H01L 29/66; H01L 29/423; H01L 29/45; H01L 21/8238; H01L 29/06; H01L 29/78; H01L 29/49

(52) U.S. Cl. CPC H01L 27/0922; H01L 29/7831; H01L 29/66492; H01L 29/4933; H01L 29/456; H01L 21/823814; H01L 29/0653; H01L 21/823878; H01L 21/823857; H01L 21/823835; H01L 29/42364

(57) ABSTRACT

A manufacturing method of a semiconductor device, comprising the following steps: providing a semiconductor substrate comprising a low-voltage device region and a high-voltage device region; forming first gate oxide layers in a non-gate region of the high-voltage device region and the low-voltage device region and a second gate oxide layer in a gate region of the high-voltage device region; the thickness of the second gate oxide layer is greater than the thickness of the first gate oxide layer; forming a first polysilicon gate and a first sidewall structure on the surface of the first gate oxide layer of the low-voltage device region and a second polysilicon gate and a second sidewall structure on the surface of the second gate oxide layer; the width of the second gate oxide layer is greater than the width of the second polysilicon gate; performing source drain ions injection to form a source drain extraction region; after depositing a metal silicide area block (SAB), performing a photolithographic etching on the metal SAB and forming metal silicide. The above manufacturing method of a semiconductor device simplifies process steps and reduces process cost. The present invention also relates to a semiconductor device.

### FIELD OF THE INVENTION

The present disclosure relates to the technical field of semiconductor manufacturing, and particularly relates to a semiconductor device and a manufacturing method thereof.

### BACKGROUND OF THE INVENTION

Among integrated circuit products, it is frequently needed to apply high-voltage devices (e.g., high-voltage metal oxide semiconductor field effect transistors), which include sources, drains and gates and the operating voltage is between 10V and 40 V. In manufacturing these products, it is often required to use a relatively thick (over 300 angstroms, to effect a higher working voltage) oxide layer to serve as a gate oxide for the high-voltage device. As the source and drain implantation (N+, P+) for a high-voltage device is typically of low energy and high volume. In the event that the thickness of the residual oxide layer in the source and drain regions of the high-voltage device is relatively thick (over 250 angstrom), the source and drain ion implantation will not reach the silicon surface, thereby cannot form a surface high doped region and causes abnormalities to the device features. Besides, a metal silicide has to be formed in the source and drain regions. In the case where there is no special step to grind the residual oxide layer in the source and drain regions of the high-voltage device, then after the metal silicide area block (SAB) is being etched, the source and drain regions of the high-voltage device will have an oxide layer residue of over 100 angstroms, such that a metal silicide cannot be normally formed in the source and drain regions of the high-voltage device, causing abnormalities to the device.

Traditionally, the manufacturing process of a high-voltage device is typically integrated with the manufacturing process of a low-voltage device. In the forming of a gate oxide layer, the thickness of the oxide layer formed on the surface of a high-voltage device is greater than that of a low-voltage device. As such, after a polysilicon image is formed, a special layer shall be added, photoresist is used to cover the low-voltage device region while all high-voltage devices are exposed, and then dry etching is employed to grind the oxide layer of the high-voltage region and the thickness of the residual oxide layer is typically kept from 50 to 150 angstroms. The oxide layer thickness difference between the high- and low-voltage device regions is within 100 angstroms, such that the subsequent source and drain implantation and metal silicide formation will not be affected. Such a manufacturing process is complex in terms of process and expensive.

### SUMMARY OF THE INVENTION

Accordingly, it is necessary to provide a simple and inexpensive method of manufacturing a semiconductor device.

A method of manufacturing a semiconductor device includes the steps of:

providing a semiconductor substrate comprising a low-voltage device region and a high-voltage device region;

forming a first gate oxide layer in a non-gate region of the high-voltage device region and the low-voltage device region, and forming a second gate oxide layer in the gate region of the high-voltage device region; a thickness of the second gate oxide layer is greater than a thickness of the first gate oxide layer;

forming a first polysilicon gate and a first sidewall structure on a surface of the first gate oxide layer of the low-voltage device region and forming a second polysilicon gate and a second sidewall structure on a surface of the second gate oxide layer; a width of the second gate oxide layer is greater than that of the second polysilicon gate;

performing source and drain ion implantation on the semiconductor substrate to form source and drain lead-out regions; and

forming a metal silicide area block on surfaces of the low-voltage device region and the high-voltage device region and performing photolithography on the metal silicide area block to expose a part of a surface of the first polysilicon gate, a part of a surface of the second polysilicon gate, and surfaces of the source and drain lead-out regions;

forming a metal silicide on the surface of the first polysilicon gate, the surface of the second polysilicon gate, and the surfaces of the source and drain lead-out regions.

A semiconductor device is also provided.

A semiconductor device includes:

a semiconductor substrate comprising a low-voltage device region and a high-voltage device region;

a first gate oxide layer formed in a non-gate region of the high-voltage device region and the low-voltage device region;

a second gate oxide layer formed in the gate region of the high-voltage device region;

a first polysilicon gate formed on a surface of the first gate oxide layer in the low-voltage device region;

a second sidewall structure formed on the surface of the first gate oxide layer in the low-voltage device region and located on a sidewall of the first polysilicon gate;

a second polysilicon gate formed on a surface of the second gate oxide layer;

a second sidewall structure formed on a surface of the second gate oxide layer and located on a sidewall of the second polysilicon gate; wherein the second polysilicon gate and the second sidewall structure are formed on the surface of the second gate oxide layer;

source and drain lead-out regions formed on the semiconductor substrate;

a metal silicide area block formed on the surfaces of the first gate oxide layer, the first polysilicon gate, the first sidewall structure, the second gate oxide layer, the second polysilicon gate and the second sidewall structure; and

a metal silicide formed in the source and drain lead-out regions, the first polysilicon gate and the second polysilicon gate.

With respect to the above-mentioned semiconductor device and the manufacturing method, in the manufacturing of the gate oxide layer, a second gate oxide layer with greater thickness is formed only in the gate region of the high-voltage device region, while a thinner first gate oxide layer is formed in other regions (the non-gate region of the high-voltage device and the low-voltage device region). Therefore, the source and drain ion implantation can be directly performed after the formation of the polysilicon gate without introducing a single processing step to grind the residual oxide layer in the high-voltage device region, thereby simplifying the processing step and reducing the processing cost.

### BRIEF DESCRIPTION OF THE DRAWINGS

The above objects, features and advantages of the present disclosure will become more apparent by describing in detail embodiments thereof with reference to the accompanying drawings. The components in the drawings are not necessarily drawn to scale, the emphasis instead being placed upon clearly illustrating the principles of the present disclosure. Moreover, in the drawings, like reference numerals designate corresponding parts throughout the views.

FIG. 1 is a flowchart of a method of manufacturing a semiconductor device according to an embodiment;

FIG. 2 is a specific flowchart of step S110 shown in FIG. 1;

FIG. 3 is a schematic view of a device after step S114 shown in FIG. 1;

FIG. 4 is a schematic view of a device after step S118 shown in FIG. 1;

FIG. 5 is a specific flowchart of step S120 shown in FIG. 1;

FIG. 6 is a schematic view of a high-voltage device region after step S120 shown in FIG. 1;

FIG. 7 is a schematic view of a high-voltage device region after step S130 shown in FIG. 1;

FIG. 8 is a schematic view of a high-voltage device region after step S140 shown in FIG. 1;

FIG. 9 is a schematic view of a high-voltage device region after step S160 shown in FIG. 1;

FIG. 10 is a schematic view of a high-voltage device region after step S170 shown in FIG. 1.

### DETAILED DESCRIPTION OF THE EMBODIMENTS

The present invention will be described in the following with reference to the accompanying drawings and the embodiments Preferably embodiments are presented in the drawings. However, numerous specific details are described hereinafter in order to facilitate a thorough understanding of the present disclosure. The various embodiments of the disclosure may, however, be embodied in many different forms and should not be construed as limited to the specific embodiments set forth hereinafter, and people skilled in the art can make similar modifications without departing from the spirit of the present disclosure.

In the present description and drawings, reference signs N and P designated for a layer or a region represent that such layer or region includes a large number of electrons or electron holes, respectively. Further, reference signs + and − designated to N or P represent that the concentration of the dopant is higher or lower than that of the layers that are not so designated. In the description and drawings of the following preferred embodiments, similar components are designated with similar reference signs and redundant explanations are omitted for brevity.

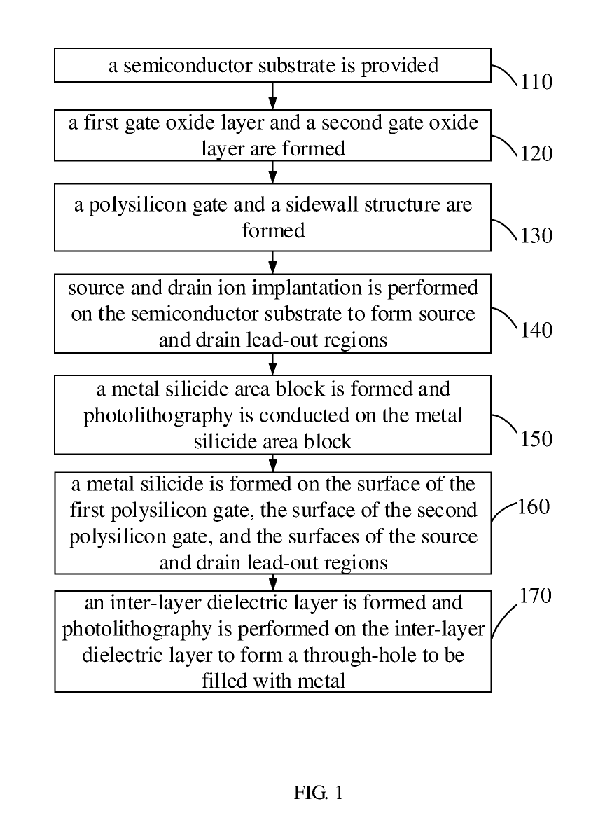

A method of manufacturing a semiconductor device can manufacture low-voltage devices and high-voltage devices at the same time. High-voltage and low-voltage are in respect to the working voltage of the devices that are manufactured at the same time, i.e., among the devices that are manufactured simultaneously, the devices with relatively higher working voltages are high-voltage devices while that with relatively lower working voltages are low-voltage devices. In the present embodiment, the low-voltage devices and the high-voltage devices manufactured are metal oxide semiconductor field effect transistor (MOS transistor). FIG. 1 is a flowchart of a method of manufacturing a semiconductor device according to an embodiment, which includes the following steps.

In step S110, a semiconductor substrate is provided.

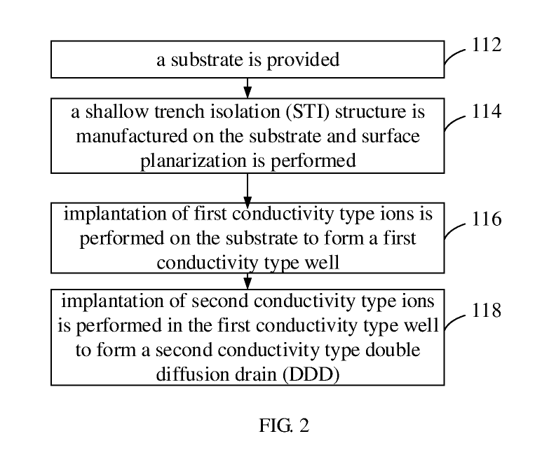

The semiconductor device requires the low-voltage device and the high-voltage device be manufactured at the same time. As such, the provided semiconductor substrate includes a high-voltage device region and a low-voltage device region. In the illustrated embodiment, the flow of the steps of providing the semiconductor substrate is shown in FIG. 2. The step of providing a semiconductor substrate includes steps S112 to S118.

In step S112, a substrate is provided.

In step S114, a shallow trench isolation (STI) structure is manufactured on the substrate and surface planarization is performed.

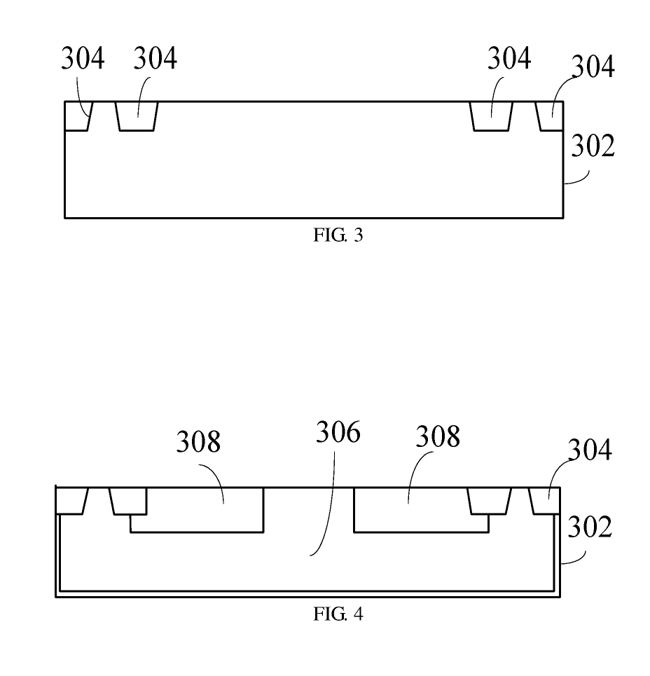

A photolithography barrier layer is formed on the surface of the substrate, a window region is formed by photolithography to the photolithography barrier layer and then a trench is formed by etching the substrate silicon. A STI structure is formed by injecting an insulating medium to the formed trench. The STI is used for isolation of the active region of the device. In the present embodiment, a chemical mechanical polishing (CMP) is performed on the surface of the device having the STI structure formed so as to effect planarization of the surface of the device. According to different technical requirements, the depth of the trench of the STI structure shall be about 3000 to 8000 angstroms. FIG. 3 is a schematic view of a device after step S114. 302 is the substrate, and 304 is the STI structure.

In step S116, implantation of first conductivity type ions is performed on the substrate to form a first conductivity type well.

In step S118, implantation of second conductivity type ions is performed in the first conductivity type well to form a second conductivity type double diffusion drain (DDD).

FIG. 4 is a schematic view of a device after step S118. As shown in FIG. 4, a first conductivity type well 306 is formed on the substrate 302, a second conductivity DDD 308 is formed on the first conductivity type well 306.

After step S118 is completed, the manufacture of the semiconductor substrate is completed.

In step S120, a first gate oxide layer and a second gate oxide layer are formed.

A first gate oxide layer is formed in the non-gate region of the high-voltage device region and the low-voltage device region, and a second gate oxide layer is formed in the gate region of the high-voltage device region. The thickness of the second gate oxide layer is greater than the thickness of the first gate oxide layer. That is because the working voltage of the high-voltage device is higher than the working voltage of the low-voltage device. Therefore, the requirements can be satisfied only when a thicker gate oxide layer is used.

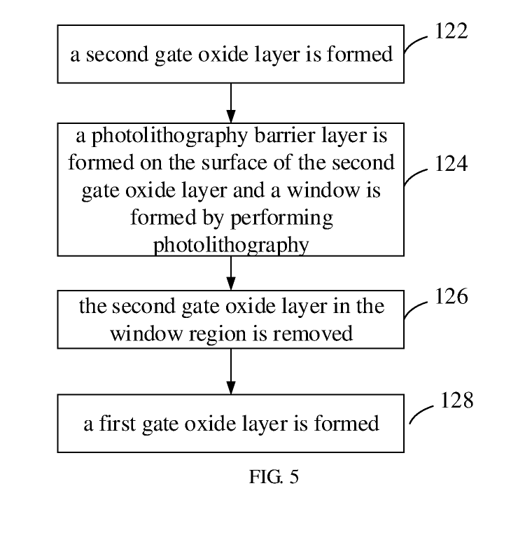

In the present embodiment, the step of forming a first gate oxide layer and a second gate oxide layer includes steps S122 to S128, as shown in FIG. 5.

In step S122, a second gate oxide layer is formed.

The second gate oxide layer is grown on the full surface of the provided semiconductor substrate. The thickness of the second gate oxide layer can be configured in accordance to the working voltage of the high-voltage device. In the present embodiment, the working voltage of the high-voltage device is between 10V and 40V, thus the thickness of the second gate oxide layer is between 300 and 700 angstroms.

In step S124, a photolithography barrier layer is formed on the surface of the second gate oxide layer and a window is formed by performing photolithography.

Photolithography is performed to the photolithography barrier layer formed on the surface of the second gate oxide layer, and a window is formed on the non-gate region of the high-voltage device region and the low-voltage device region.

In step S126, the second gate oxide layer in the window region is removed.

The second gate oxide layer in the window region is removed when the photolithography barrier layer serves as the mask, such that the surfaces of the semiconductor substrate of the non-gate region of the high-voltage device region and the low-voltage device region are exposed.

In step S128, a first gate oxide layer is formed.

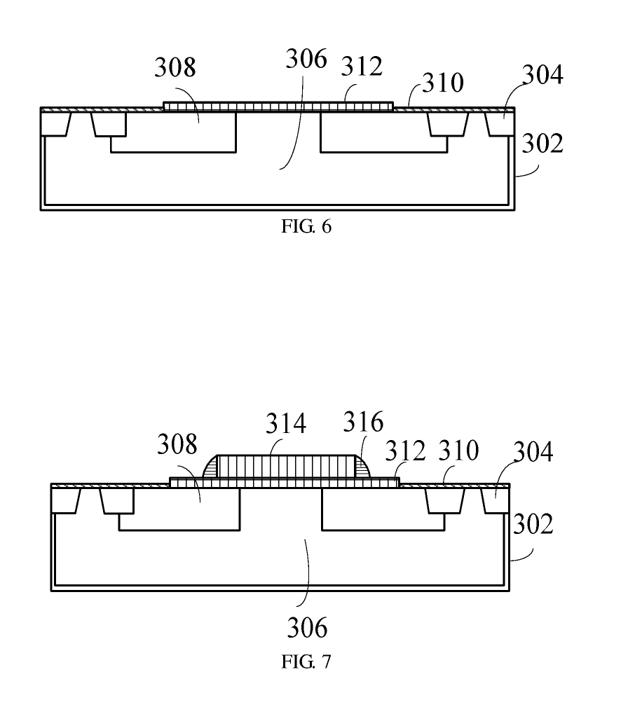

A first gate oxide layer is formed on the surface of the semiconductor substrate. In the present embodiment, the thickness of the first gate oxide layer formed is between 20 and 80 angstroms. After the first gate oxide layer is formed, it is further required to remove the photolithography barrier layer. FIG. 6 is a schematic view of a high-voltage device region after step S128. 310 is the first gate oxide layer, 312 is the second oxide layer located in the gate region of the high-voltage device region.

The gate oxide layer is manufactured through step S120 such that the second gate oxide layer 312 with a relatively greater thickness is formed in the gate region of the high-voltage device region, while the first gate oxide layer 310 with a relatively smaller thickness is formed in other regions (the non-gate region of the high-voltage device region and the low-voltage device region). However, a second gate oxide layer with a relatively greater thickness is formed on the full surface of the high-voltage device region in the conventional manufacturing process.

In step S130, a polysilicon gate and a sidewall structure are formed.

Specifically, a first polysilicon gate and a first sidewall structure are formed on the surface of the first gate oxide layer of the low-voltage device region, the first sidewall structure being as well located on a lateral side of the first polysilicon gate at the same time. A second polysilicon gate as well as a second sidewall structure are formed on the surface of the second gate oxide layer of the high-voltage device. The width of the second gate oxide layer is greater than the width of the second polysilicon gate. In the present embodiment, the width of the second gate oxide layer formed is 0.2 to 1 micrometers greater than the width of the second polysilicon gate, and the specific size being adjustable according to the feature requirements of the device. As the second gate oxide layer of the high-voltage device is required to endure high voltage, in the case where the second gate oxide layer is not extended by a certain size, due to the difference in the alignment of the photolithography, the thickness of the marginal region of the second gate oxide layer may fail to meet the voltage tolerance requirement, thereby failing to satisfy the high-voltage tolerance requirement of the high-voltage device and resulting in problems with the device. In the present embodiment, the second sidewall structure of the high-voltage device is located on the sidewall of the second polysilicon gate, as well as on the surface of the second gate oxide layer (i.e. not in contact with the surface of the second conductivity DDD). FIG. 7 is a schematic view of a high-voltage device region after step S130. 314 is the second polysilicon gate, and 316 is the second sidewall structure. As the manufacture of the first sidewall structure and the first polysilicon gate of the low-voltage device region and the manufacture of the high-voltage device are the same, the introduction is omitted for brevity.

In step S140, source and drain ion implantation is performed on the semiconductor substrate to form source and drain lead-out regions.

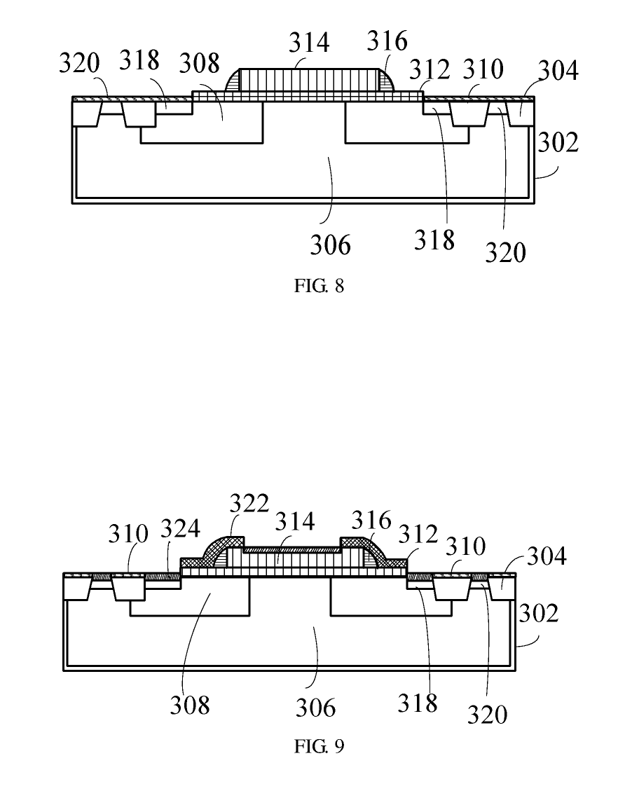

Source and drain ion implantation is performed on the semiconductor substrates of the low-voltage device region as well as the high-voltage device region to respectively form source and drain lead-out regions. FIG. 8 is a schematic view of a high-voltage device region after step S140. Implantation of second conductivity ions is performed in the second conductivity DDD 308 to form second conductivity type source and drain lead-out regions 318. On the first conductivity type well 306 and between the region STI structures 304, implantation of first conductivity type ions is performed to form first conductivity type source and drain lead-out regions 320.

In step S150, a metal silicide area block is formed and photolithography is conducted on the metal silicide area block.

A metal silicide area block (SAB) is formed on the surfaces of the low-voltage device region and the high-voltage device region, which metal silicide area block can be a silicon oxide. Photolithography is performed on the formed metal silicide area block to expose part of the surface of the first polysilicon gate, part of the surface of the second polysilicon gate, and the surfaces of the source and drain lead-out regions.

In step S160, a metal silicide is formed on the surface of the first polysilicon gate, the surface of the second polysilicon gate, and the surfaces of the source and drain lead-out regions.

On the surface of the first polysilicon gate, the surface of the second polysilicon gate, and the surfaces of the source and drain lead-out regions are exposed, a metal silicide is formed. The manufacturing of metal silicide can employ the manufacturing processes that are commonly used in the art concerned. FIG. 9 is a schematic view of a high-voltage device region after step S160. 322 is the metal silicide area block, and 324 is the metal silicide. In the present embodiment, the metal silicide area block 322 of the high-voltage device is located on the surface of the second gate oxide layer 312 as well as on part of the surfaces of the second sidewall structure 316 and the second polysilicon gate 314. The metal silicide 324 is formed on the first conductivity type source and drain lead-out regions 320, the second conductivity type source and drain lead-out regions 318 and the second polysilicon gate 314.

In the conventional manufacturing process, as a second gate oxide layer with relatively great thickness is formed on the whole surface of the high-voltage device region, after a polysilicon image is formed, a special layer shall be added, a photoresist is used to cover the low-voltage device region while all high-voltage devices are exposed, and then dry etching is employed to grind the oxide layer of the high-voltage region and the thickness of the residual oxide layer is typically kept from 50 to 150 angstroms. The oxide layer thickness difference between the high- and low-voltage device regions is within 100 angstroms, such that the subsequent source and drain implantation and metal silicide formation will not be affected. However, the manufacturing process is complex and the cost is relatively high. In the present embodiment, in the manufacture of gate oxide layer, as the second gate oxide layer 312 with a relatively greater thickness is only formed in the gate region of the high-voltage device region, and a first gate oxide layer 310 with relatively smaller thickness is formed in other regions (the non-gate region of a high-voltage device and the low-voltage device region). As such, after the second polysilicon gate 314 and the second sidewall structure 316 are formed, implantation of source and drain ions can be performed directly without introducing an individual process/step to grind the gate oxide layer of the high-voltage device region, such that the process is simplified whilst the cost is also reduced.

In the present embodiment, the first conductivity type is a P type while the second conductivity type is an N type, i.e., the semiconductor device manufactured is an NMOS device. In other embodiments, the first conductivity type can be an N type while the second conductivity type can be a P type, i.e., the semiconductor device manufactured is a PMOS device.

In the present embodiment, step S170 is further performed.

In step S170, an inter-layer dielectric layer is formed and photolithography is performed on the inter-layer dielectric layer to form a through-hole to be filled with metal.

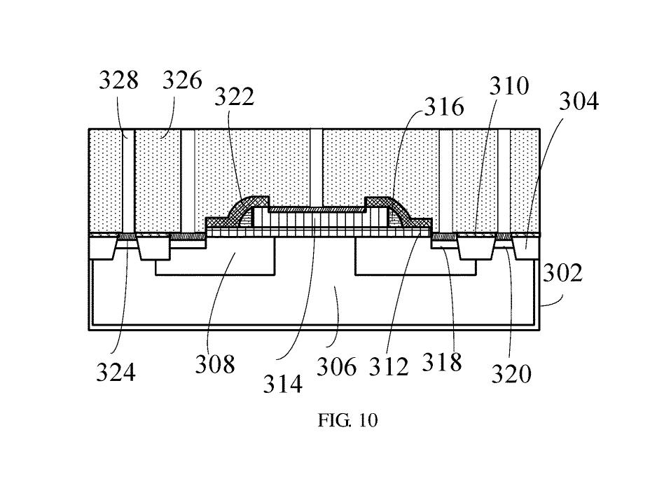

An inter-layer dielectric (ILD) deposition will be performed on the surface of a formed device, and photolithography is performed to form a through-hole. After the through-hole is formed, the through-hole is filled with metal to effect connection of the device. FIG. 10 is a schematic view of a high-voltage device region after step S170. 326 is the inter-layer dielectric layer, and 328 is the formed through-hole structure inside which an conductivity metal is filled.

The present disclosure further provides a semiconductor device, which is obtained through the method of manufacturing the semiconductor device in the foregoing embodiments. The semiconductor device includes: a semiconductor substrate including a low-voltage device region and a high-voltage device region; a first gate oxide layer formed in the non-gate region of a high-voltage device region and in the low-voltage device region, and a second gate oxide layer formed on the surface of the gate region of the high-voltage device region; a first sidewall structure and a first polysilicon gate formed on the surface of the first gate oxide layer of the low-voltage device region; a second sidewall structure and a second polysilicon gate formed on the surface of the second gate oxide layer, the width of the second gate oxide layer being greater than the width of the second polysilicon gate; source and drain lead-out regions formed on the semiconductor substrate; a metal silicide area block formed on the surfaces of the first gate oxide layer, the first polysilicon gate, the second sidewall structure, the second gate oxide layer, the second polysilicon gate and the second sidewall structure; and a metal silicide formed on the source and drain lead-out regions, the first polysilicon gate and the second polysilicon gate. In the present embodiment, devices in both the low-voltage device region and high-voltage device region of the semiconductor device are double diffused drain (DDD) type MOS transistors.

FIG. 10 is a schematic view of a high-voltage device region of the semiconductor device. The high-voltage region includes: a substrate 302, a first conductivity type well 306 and a STI structure 304 formed on the substrate 302; a second conductivity DDD 308 formed on the first conductivity type well 306; a first gate oxide layer 310 formed on the surface of the STI structure 304; a second gate oxide layer 312 formed on the surface of the gate region of the device; a second sidewall structure 316 and a second polysilicon gate 314 formed on the surface of the second gate oxide layer 312; second conductivity type source and drain lead-out regions 318 formed on the second conductivity type DDD 308; first conductivity type source and drain lead-out regions 320 formed on the first conductivity type well 304; a metal silicide area block 322 formed on the surfaces of the second gate oxide layer 312, the second sidewall structure 316 and the second polysilicon gate 314; a metal silicide 324 formed on the second polysilicon gate 314, the first conductivity type source and drain lead-out regions 320 and the second conductivity type source and drain lead-out regions 318; and an inter-layer dielectric layer 326 formed on the surface of the device. In the inter-layer dielectric layer 326 is formed a through-hole 328 to be filled with metal to effect connection of the device. In the present embodiment, the width of the second gate oxide layer 312 formed is 0.2 to 1 micrometers greater than the width of the second polysilicon gate 314, the specific size being adjustable according to the feature requirements of the device. As the second gate oxide layer of the high-voltage device is required to endure a high voltage, in the case where the second gate oxide layer is not extended by a certain size, due to the difference in the alignment of the photolithography, the thickness of the marginal region of the second gate oxide layer may fail to meet the voltage tolerance requirement, thereby failing to satisfy the high-voltage tolerance requirement of the high-voltage device and resulting in problems with the device. The first conductivity type is a P type while the second conductivity type is an N type. In other embodiments, the first conductivity type can be an N type while the second conductivity type can be a P type.

The respective technical features of the above embodiments above can have various combinations. which are not described for the purpose of brevity. Nevertheless, to the extent the combining of the different technical features do not conflict with each other, all such combinations must should be regarded as within the scope of the disclosure.

The foregoing implementations are merely specific embodiments of the present disclosure, and are not intended to limit the protection scope of the present disclosure. It should be noted that any variation or replacement readily figured out by persons skilled in the art disclosure within the technical scope disclosed in the present disclosure shall all fall within the protection scope of the present disclosure. Therefore, the protection scope of the present disclosure shall be subject to the protection scope of the claims.

1. A method of manufacturing a semiconductor device, comprising the steps of:
providing a semiconductor substrate comprising a low-voltage device region and a high-voltage device region;
forming a first gate oxide layer in a non-gate region of the high-voltage device region and the low-voltage device region, and forming a second gate oxide layer in a gate region of the high-voltage device region; wherein a thickness of the second gate oxide layer is greater than a thickness of the first gate oxide layer;
forming a first polysilicon gate and a first sidewall structure on a surface of the first gate oxide layer of the low-voltage device region, and forming a second polysilicon gate and a second sidewall structure on a surface of the second gate oxide layer; wherein a width of the second gate oxide layer is greater than a width of the second polysilicon gate;
performing source and drain ion implantation on the semiconductor substrate and forming source and drain lead-out regions;
forming a metal silicide area block on surfaces of the low-voltage device region and the high-voltage device region, and performing photolithography to the metal silicide area block to expose a part of a surface of the first polysilicon gate, a part of a surface of the second polysilicon gate, and surfaces of the source and drain lead-out regions; and
forming a metal silicide on the surface of the first polysilicon gate, the surface of the second polysilicon gate, and the surfaces of the source and drain lead-out regions.

2. The method of claim 1, wherein the width of the second gate oxide layer is 0.2 to 1 micrometers greater than the width of the second polysilicon gate.

3. The method of claim 1, wherein the step of forming a first gate oxide layer in the non-gate region of the high-voltage device region and the low-voltage device region and forming a second gate oxide layer in the gate region of the high-voltage device region comprises:
forming a second gate oxide layer on the semiconductor substrate;
forming a photolithography barrier layer on the second gate oxide layer and performing photolithography thereto form a window in the non-gate region of the high-voltage device region and the low-voltage device region;
removing the second gate oxide layer in the window using the photolithography barrier layer as a mask layer;
forming a first gate oxide layer on a surface of the semiconductor substrate; and
removing the photolithography barrier layer.

4. The method of claim 1, wherein the thickness of the first gate oxide layer is 20 to 80 angstroms, and the thickness of the second gate oxide layer is 300 to 700 angstroms.

5. The method of claim 1, wherein after the step of forming the metal silicide on the surface of the first polysilicon gate, the surface of the second polysilicon gate, and the surfaces of the source and drain lead-out regions, the method further comprises:
forming an inter-layer dielectric layer on the surfaces of the high-voltage device region and the low-voltage device region;
performing photolithography on the inter-layer dielectric layer to form a through hole; and
filling the through hole with metal.

6. The method of claim 1, wherein the step of providing a semiconductor substrate comprising a low-voltage device region and a high-voltage device region comprises:
providing a substrate;
manufacturing a shallow trench isolation (STI) structure on the substrate and performing a surface planarization;
performing a first conductivity type ion implantation on the substrate and forming a first conductivity type well; and
performing a second conductivity ion implantation in the first conductivity type well and forming a second conductivity type double diffused drain (DDD).

7. The method of claim 6, wherein the first conductivity type is a P type and the second conductivity type is an N type.

8. The method of claim 6, wherein the first conductivity type is an N type and the second conductivity type is a P type.

9. A semiconductor device, comprising:
a semiconductor substrate comprising a low-voltage device region and a high-voltage device region;
a first gate oxide layer formed in a non-gate region of the high-voltage device region and the low-voltage device region;
a second gate oxide layer formed in a gate region of the high-voltage device region;
a first polysilicon gate formed on a surface of the first gate oxide layer in the low-voltage device region;
a first sidewall structure formed on the surface of the first gate oxide layer in the low-voltage device region and located on a sidewall of the first polysilicon gate;
a second polysilicon gate formed on a surface of the second gate oxide layer;
a second sidewall structure formed on a surface of the second gate oxide layer and located on a sidewall of the second polysilicon gate;
source and drain lead-out regions formed on the semiconductor substrate;
a metal silicide area block formed on surfaces of the first gate oxide layer, the first polysilicon gate, the first sidewall structure, the second gate oxide layer, the second polysilicon gate and the second sidewall structure; and
a metal silicide formed in the source and drain lead-out regions, the first polysilicon gate and the second polysilicon gate.

10. The device of claim 9, wherein the width of the second gate oxide layer is 0.2 to 1 micrometers greater than the width of the second polysilicon gate.

11. The device of claim 9, wherein the thickness of the first gate oxide layer is 20 to 80 angstroms, and the thickness of the second gate oxide layer is 300 to 700 angstroms.
